(19) United States
(12) Patent Application Publication
(10) Pub. No.: US 2008/0042123 A1
(43) Pub. Date: Feb. 21, 2008

(54) Methods for controlling thickness uniformity of SiGe regions

(76) Inventors: Kong-Beng Thei, Hsin-Chu (TW); Harry Chuang, Austin, TX (US); Yuan-Chen Sun, Hsinchu (TW)

Correspondence Address: SLATER & MATSIL, L.L.P., 17950 PRESTON ROAD, SUITE 1000, DALLAS, TX, 75252, US

(21) Appl. No.: 11/699,611

(22) Filed: Jan. 30, 2007

Related U.S. Application Data
(60) Provisional application No. 60/838,813, filed on Aug. 18, 2006.

(51) Int. Cl. H01L 31/00

(52) U.S. Cl. 257/19

(57) ABSTRACT

An integrated circuit includes a semiconductor substrate having a first region, at least one p-type region in the semiconductor substrate having SiGe regions formed therein, and at least one n-type region in the semiconductor substrate. All SiGe regions in the first region have a first combined area. All p-type regions in the first region have a second combined area. All n-type regions in the first region have a third combined area. The ratio of the first combined area to a total area of the second combined area and the third combined area is less than about 30 percent.

This application claims the benefit of U.S. Provisional Application No. 60/838,813, filed on Aug. 18, 2006, entitled “Methods for Controlling Thickness Uniformity of SiGe Regions;” which application is hereby incorporated herein by reference.

### TECHNICAL FIELD

This invention relates generally to integrated circuits, and more particularly to the formation of SiGe stressors of PMOS devices.

### BACKGROUND

Reductions in the size of semiconductor devices (e.g., a metal-oxide semiconductor device) have enabled continued improvement in speed, performance, density, and cost per unit function of integrated circuits over the past few decades. In accordance with the design of a transistor and one of the inherent characteristics thereof, modulating the length of a channel region underlying a gate between a source and a drain of the transistor alters a resistance associated with the channel region, thereby affecting the performance of the transistor. More specifically, shortening the length of the channel region reduces a source-to-drain resistance of the transistor, which, assuming other parameters are maintained relatively constant, may allow an increase in current flow between the source and drain when a sufficient voltage is applied to the gate of the transistor.

To further enhance the performance of MOS devices, stress may be introduced in the channel region of a MOS transistor to improve carrier mobility. Generally, it is desirable to induce a tensile stress in the channel region of an n-type metal-oxide-semiconductor (“NMOS”) device in a source-to-drain direction and to induce a compressive stress in the channel region of a p-type metal-oxide-semiconductor (“PMOS”) device in a source-to-drain direction.

A commonly used method for applying compressive stresses to the channel regions of PMOS devices is to grow SiGe stressors in the source and drain regions. Such a method typically includes the steps of forming a gate stack on a semiconductor substrate, forming gate spacers on sidewalls of the gate stack, forming recesses in the silicon substrate, and epitaxially growing SiGe stressors in the recesses. Since SiGe has a greater lattice constant than silicon, it applies a compressive stress to the channel region, which is located between a source SiGe stressor and a drain SiGe stressor.

The epitaxy process of SiGe suffers from uniformity problems. FIG. 1 schematically illustrates a conventional PMOS device 2 having SiGe stressors 4. Partially due to pattern-loading effects, the thickness of SiGe stressors 4 is not uniform, and humps may be formed. The thickness variation of SiGe stressors will degrade drive currents of PMOS devices.

Traditionally, non-uniformity in the thickness of SiGe regions was reduced via the control of germanium concentrations, which was achieved by adjusting epitaxy process parameters, such as gas flow, reaction pressure, power, etc. However, controlling epitaxy process parameters may reduce wafer throughput in the manufacturing process of integrated circuits. In addition, contamination may be introduced. Therefore, improved methods for solving thickness non-uniformity problems of SiGe regions are needed.

### SUMMARY OF THE INVENTION

In accordance with one aspect of the present invention, an integrated circuit includes a semiconductor substrate having a first region, at least one p-type region in the semiconductor substrate having SiGe regions formed therein, and at least one n-type region in the semiconductor substrate. All SiGe regions in the first region have a first combined area. All p-type regions in the first region have a second combined area. All n-type regions in the first region have a third combined area. A ratio of the first combined area to a total area of the second combined area and the third combined area is less than about 30 percent.

In accordance with another aspect of the present invention, an integrated circuit includes a semiconductor substrate; a first region comprising core devices in the semiconductor substrate, a second region comprising input/output devices in the semiconductor substrate; a third region comprising memory devices in the semiconductor substrate, wherein each of the first region, the second region and the third region has an area of greater than about 5×5 mm²; at least one p-type region in each of the first region, the second region and the third region, wherein the at least one p-type region comprises SiGe formed therein; and at least one n-type region in each of the first region, the second region and the third region. All SiGe regions in the first, the second and the third regions have a first combined area. All p-type regions in the first, the second and the third regions have a second combined area. All n-type regions in the first, the second and the third regions have a third combined area. A ratio of the first combined area to a total area of the second combined area and the third combined area is less than about 30 percent.

In accordance with yet another aspect of the present invention, a mask set for forming an integrated circuit includes a first region defined in more than one mask in the mask set, a plurality of first patterns in the first region, wherein the plurality of first patterns defines p-type regions and n-type regions, and a plurality of second patterns in the first region, wherein the plurality of second patterns defines SiGe regions. The p-type regions comprise the plurality of second patterns and possibly additional patterns. The first patterns have a first combined area. The second patterns have a second combined area. A ratio of the second combined area to the first combined area is less than about 30 percent.

An advantageous feature of the present invention is that by reducing the pattern density of SiGe regions, the uniformity in the thickness of SiGe regions is improved.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional PMOS device having SiGe stressors, wherein the thickness of SiGe stressors is not uniform;

FIGS. 2 and 3 illustrate a cross-sectional view and a top view of a substrate, respectively, wherein a p-type active region, a p-type inactive region, an n-type active region and an n-type inactive region are defined;

FIG. 4 illustrates thickness uniformities of SiGe regions as a function of pattern densities;

FIG. 5 illustrates thickness uniformities of SiGe regions as a function of SiGe mask clear ratios;

FIG. 6 illustrates embodiments of the present invention, wherein portions of p-type inactive regions are masked during the formation of SiGe regions; and

FIG. 7 illustrates further embodiments of the present invention, wherein portions of p-type active regions are masked during the formation of SiGe regions.

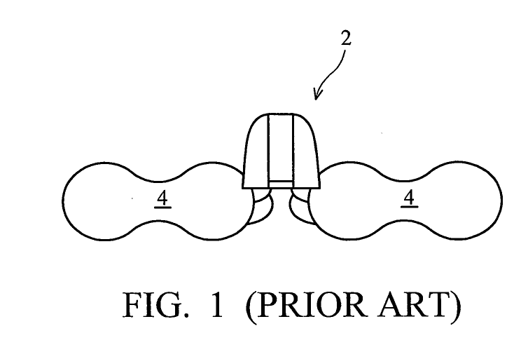

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

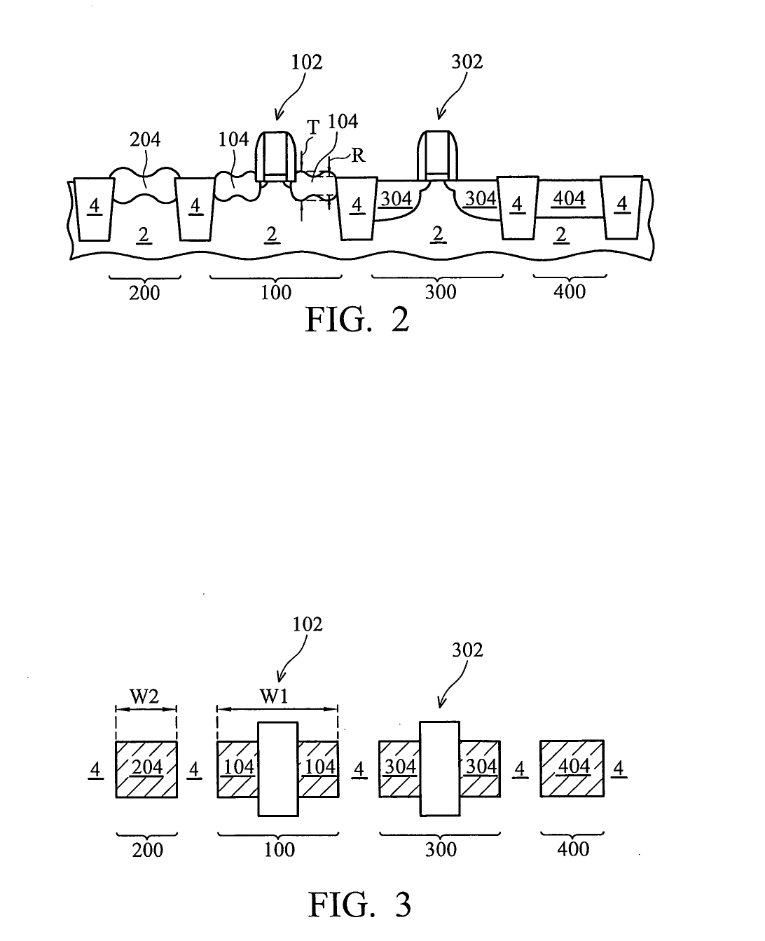

Experiments performed by inventors have revealed that uniformities of SiGe regions are related to pattern densities. A definition of the pattern density and other concepts involved in the present invention are explained using FIGS. 2 and 3. Referring to FIG. 2, a substrate 2 includes a p-type metal-oxide-semiconductor (PMOS) region 100 for forming a PMOS device 102, a dummy PMOS region 200, an n-type metal-oxide-semiconductor (NMOS) region 300 for forming an NMOS device 302 and a dummy NMOS region 400. As is known in the art, substrate 2 is preferably a silicon substrate. Alternatively, other Group III or Group IV compounds may be used. Each of the device regions, 100, 200, 300 and 400, may belong to a core circuit region, an input/output (I/O) circuit region, a memory region, or other circuit regions in which SiGe regions are preferred. Substrate 2 (or the chip) may also include other regions having or not having SiGe regions, such as static random access memory (SRAM) regions, eSRAM regions, 1T-RAM regions, and the like. Furthermore, substrate 2 may further include analog regions, which includes analog devices such as bipolar junction transistors, resistors, capacitors, diodes, seal rings, and the like.

Regions 100, 200, 300 and 400 are separated by insulation regions 4, which may be shallow trench isolation regions. PMOS device 102 comprises SiGe regions 104. In order to reduce pattern-loading effects, at the time SiGe regions 104 are formed, dummy SiGe region 204 is also formed. NMOS device 302 includes source/drain regions 304, which may be formed by implanting an n-type impurity into substrate 2. Alternatively, source/drain regions 304 may comprise SiC stressors. Similarly, to reduce pattern-loading effects in the formation of NMOS devices, NMOS dummy region 404 is formed in region 400, for example, by simultaneously implanting an n-type impurity into regions 300 and 400.

It is to be noted that when the germanium concentration in SiGe regions is lowered, the thickness uniformity problems are less severe. In the preferred embodiment, the germanium concentration in SiGe regions 104 and 204 are preferably between about 5 percent and about 40 percent. As is known in the art, metal silicide regions (not shown) will be formed on SiGe regions 104, and possibly on SiGe region 204.

FIG. 3 illustrates a top view of the structure shown in FIG. 2. Throughout the description, the regions that are available for forming SiGe stressors of PMOS devices, such as regions 104, are equally referred to as p-type active regions. The regions for forming source/drain regions of NMOS devices, such as regions 304, are referred to as n-type active regions. Dummy PMOS region 204 is a p-type inactive region. Dummy NMOS region 404 is an n-type inactive region. P-type active regions 104, p-type inactive region 204, n-type active regions 304 and n-type inactive region 404 are shaded for easy identification. Please note that in FIG. 2, SiGe is formed in the entire p-type active regions 104 and p-type inactive region 204. However, in subsequently discussed embodiments, SiGe may be formed only in portions of p-type active regions 104 and p-type inactive region 204.

In any specified region, which may include an entire chip or only a sub-region of a chip, a pattern density of SiGe regions is defined as A1/(A2+A3), wherein area A1 is a combined (or total) area of all SiGe regions in the specified region. Area A2 is a combined area of all p-type regions, including p-type active regions and p-type inactive regions, in the specified region. Area A3 is a combined area of all n-type regions, including n-type active regions and n-type inactive regions, in the specified region. It is noted that if SiGe is formed in all p-type active regions and p-type inactive regions, area A1 will be equal to area A2, and the pattern density may be expressed as A2/(A2+A3). Apparently, if the specified region only includes the regions illustrated in FIG. 2, the pattern density may be expressed as (a1+b1)/(a1+a2+b1+b2), wherein a1 is a combined area of p-type active regions 104, a2 is a combined area of n-type active regions 304, b1 is an area of p-type inactive region 204, and b2 is an area of n-type inactive region 404.

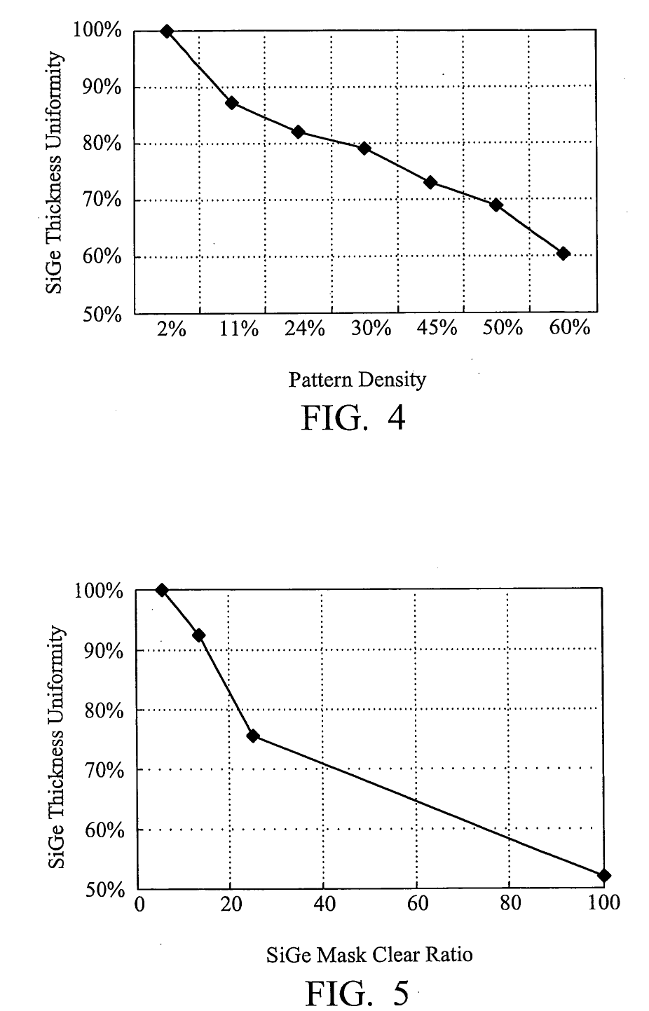

FIGS. 4 and 5 are experiment results, which illustrate how thickness uniformities of SiGe regions are affected by pattern densities. The definition of thickness uniformity of a SiGe region may be found in FIG. 2. SiGe regions 104 have portions recessed than other portions, wherein the recessed portions are typically in central regions of SiGe regions 104. The recessed portions thus have a smaller thickness than non-recessed portions. Assuming the thickness of SiGe regions 104 in recessed portions have a depth R, further assuming that the non-recessed portions have a thickness of T, the uniformity is R/T, which may be represented with a percentage.

Referring back to FIG. 4, the Y-axis represents thickness uniformities of SiGe regions, and the Y-axis represents pattern densities, wherein the illustrated pattern densities are calculated in regions having sizes of 5×5 mm². It is noted that the thickness uniformities of SiGe regions are correlated to the pattern densities. With the decrease in the pattern densities, the thickness uniformities of SiGe regions are improved. In the preferred embodiment, the uniformities of SiGe regions are preferably greater than about 80 percent. Accordingly, it is found from FIG. 4 that the preferred pattern densities of SiGe regions are less than about 30 percent.

FIG. 5 illustrates thickness uniformities of SiGe regions as a function of SiGe mask clear ratios, wherein SiGe mask clear ratios are equal to the total area of SiGe regions in a chip divided by the area of the entire chip. Similar to the conclusion drawn from FIG. 4, with the decrease in the SiGe mask clear ratios, the uniformities of SiGe regions are improved. With a preferred thickness uniformity of greater than about 80 percent, it is found from FIG. 5 that SiGe mask clear ratios are preferably less than about 20 percent. In the preferred embodiment, the total area of all SiGe regions in an entire chip is preferably less than about 20 percent of the area of all p-type and n-type regions in the chip, including active and inactive regions.

Preferably, to control pattern densities in a sub-region on a chip to less than about 30 percent or the pattern density of an entire chip to less than about 20 percent, the areas of SiGe regions need to be reduced.

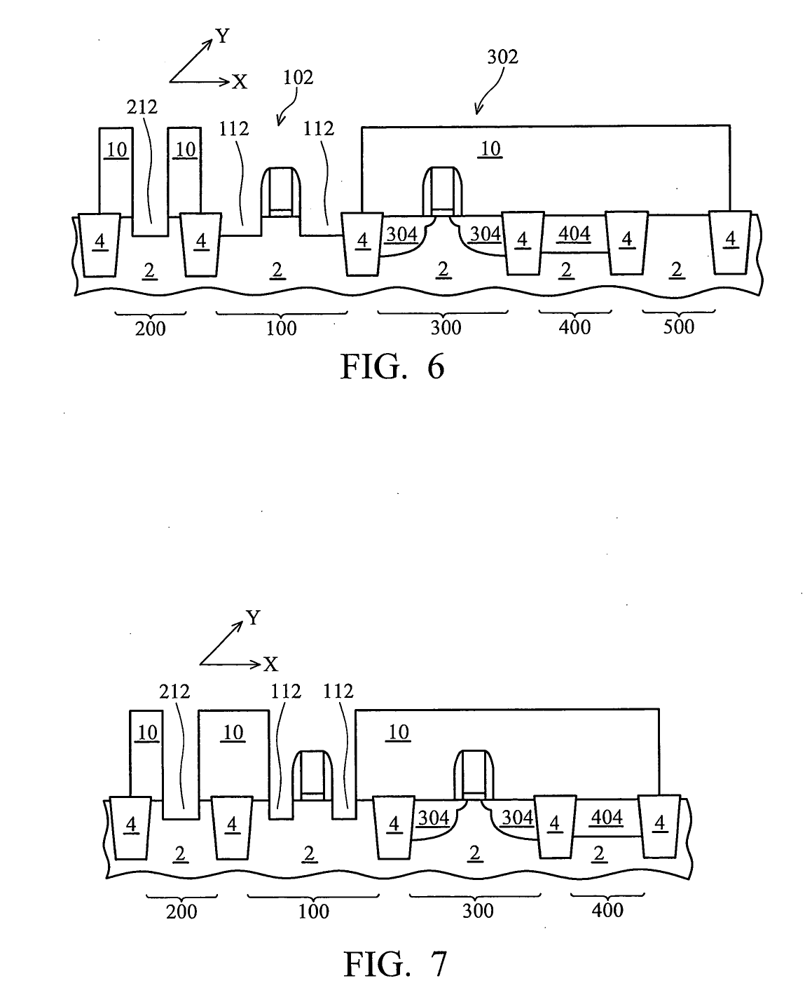

A first and a second embodiment for controlling the pattern density of SiGe regions are illustrated in FIG. 6, wherein SiGe regions are formed in only portions of dummy PMOS regions 200 and 500. In order to form recesses 112 and 212, which will be filled with SiGe regions 104 and 204 (refer to FIG. 2), respectively, a revised mask is needed. The revised mask is then used to form photo resist 10. In the first embodiment, the patterns in the revised mask covers portions of dummy PMOS region 200, and thus the recess 212, hence the resulting dummy SiGe region, is smaller than p-type inactive region 200. In this case, the area A1 for calculating the pattern density only includes the area of recess 212, but not the entire p-type inactive region 200. As a result, the pattern density is reduced. Assuming X direction is in the plane of the cross-sectional view shown in FIG. 6, and Y direction is perpendicular to the plane of the cross-sectional view shown in FIG. 6, the dimension of recess 212 may be reduced in X and/or Y directions.

In a second embodiment, as also shown in FIG. 6, a p-type inactive region 500 is completely masked by photo resist 10. Therefore, no SiGe region will be formed in region 500, and thus area A1 does not take the area of p-type inactive region 500 into account.

FIG. 7 illustrates a third embodiment of the present invention, wherein SiGe is not formed in portions of p-type active regions. Recesses 112 only occupy portions of the p-type active regions in region 100. This is achieved by extending photo resist 10 on portions of p-type active region in region 100. Accordingly, the SiGe regions formed in recesses 112 will be smaller than the respective p-type active regions in region 100. Assuming X direction is in the plane of the cross-sectional view shown in FIG. 7, and Y direction is perpendicular to the plane of the cross-sectional view shown in FIG. 7, the dimensions of recesses 112 are preferably reduced only in X direction, or channel length direction, as is shown in FIG. 7. The dimensions of SiGe regions in Y direction are preferably not reduced. Accordingly, the widths (in Y direction) of the SiGe regions in the p-type active regions are preferably equal to the widths of the respective p-type active regions, while the lengths (in X direction) of the SiGe regions in the p-type active regions may be less than the lengths of the respective p-type active regions. One skilled in the art will realize that the embodiments shown in FIGS. 6 and 7 may be combined to reduce the areas of SiGe regions in p-type active regions and p-type inactive region, simultaneously.

An advantageous feature of the embodiments shown in FIGS. 6 and 7 is that less design changes are required. Since sizes and locations of active regions 100 and 300 and inactive regions 200, 400 and 500 do not need to be changed, the sizes and locations of STI regions 4 and NMOS device 102 do not need to be changed. Accordingly, the masks for forming STI regions and NMOS devices do not need to be changed.

In the embodiments shown in FIGS. 6 and 7, the revised mask for forming photo resist 10 may be formed by applying logic operations (LOP) and/or optical proximity corrections (OPC) to a conventional mask (or a binary definition file, often referred to as GDS file, which defines layers in the manufacture of integrated circuits), in which regions such as 100, 200, 300, 400, 500, 104 and 204 are defined. Through LOP and/or OPC, the boundary of the conventional mask may be revised as required.

In the preferred embodiment, after performing the embodiments of the present invention, across an entire chip, the pattern density is preferably less than about 20 percent, and more preferably between about 8 percent and about 20 percent. Furthermore, in a sub-region having an area of greater than about 10×10 mm², the pattern density is preferably less than about 30 percent, and more preferably between about 5 percent and about 30 percent. Alternatively, in a sub-region having an area of greater than about 5×5 mm², the pattern density is preferably less than about 30 percent, and more preferably between about 5 percent and about 30 percent. Furthermore, when calculating a pattern density for a sub-region, the sub-region may include more than one functional circuit region, such as an input/output region, a memory region, a core device region, and the like. In this case, each of the functional circuit regions in the sub-region preferably has an area of greater than about 5×5 mm².

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit comprising:
a semiconductor substrate having a first region;
at least one p-type region in the semiconductor substrate having SiGe regions formed therein;
at least one n-type region in the semiconductor substrate;
wherein all SiGe regions in the first region have a first combined area, and wherein all p-type regions in the first region have a second combined area, and wherein all n-type regions in the first region have a third combined area; and
wherein a ratio of the first combined area to a total area of the second combined area and the third combined area is less than about 30 percent.

2. The integrate circuit of claim 1, wherein the first region comprises an entire chip.

3. The integrate circuit of claim 2, wherein the ratio is between about 8 percent and about 20 percent.

4. The integrated circuit of claim 1, wherein the first region has a width and a length each being greater than about 5 mm.

5. The integrated circuit of claim 4, wherein the first region has a width and a length each being greater than about 10 mm.

6. The integrated circuit of claim 4, wherein the ratio is between about 5 percent and about 30 percent.

7. The integrated circuit of claim 1, wherein the p-type regions in the first region comprise p-type active regions and p-type inactive regions, and wherein the n-type regions in the first region comprise n-type active regions and n-type inactive regions.

8. The integrated circuit of claim 7, wherein at least one of the p-type inactive regions is free from SiGe.

9. The integrated circuit of claim 7, wherein at least one of the p-type inactive regions comprises a first portion and a second portion, and wherein the first portion comprises SiGe, and the second portion is free from SiGe.

10. The integrated circuit of claim 7, wherein a p-type active region in the p-type active regions comprises a first portion and a second portion, and wherein the first portion comprises SiGe, and the second portion is free from SiGe, and wherein a width of the SiGe in the p-type active region is equal to a width of the p-type active region.

11. The integrated circuit of claim 1, wherein the first region is a circuit region selected from the group consisting essentially of a core region, an input/output region, a memory region, and combinations thereof.

12. The integrated circuit of claim 1 further comprising a second region comprising devices selected from the group consisting essentially of SRAM, eDRAM, 1T-RAM, and combinations thereof.

13. An integrated circuit comprising:
a semiconductor substrate;
a first region comprising core devices in the semiconductor substrate;
a second region comprising input/output devices in the semiconductor substrate;
a third region comprising memory devices in the semiconductor substrate, wherein each of the first region, the second region and the third region has an area of greater than about 5×5 mm²;
at least one p-type region in each of the first region, the second region and the third region, wherein the at least one p-type region comprises SiGe formed therein;
at least one n-type region in each of the first region, the second region and the third region;
wherein all SiGe regions in the first, the second and the third regions have a first combined area, and wherein all p-type regions in the first, the second and the third regions have a second combined area, and wherein all n-type regions in the first, the second and the third regions have a third combined area; and
wherein a ratio of the first combined area to a total area of the second combined area and the third combined area is less than about 30 percent.

14. The integrated circuit of claim 13 further comprising a fourth region, wherein the fourth region comprises devices selected from the group consisting essentially of bipolar junction transistors, resistors, capacitors, diodes, seal rings, and combinations thereof.

15. A mask set for forming an integrated circuit, the mask set comprising:
a first region defined in more than one mask in the mask set;
a plurality of first patterns in the first region, wherein the plurality of first patterns defines p-type regions and n-type regions;
a plurality of second patterns in the first region, wherein the plurality of second patterns defines SiGe regions, and wherein the p-type regions comprise the plurality of second patterns;
wherein the first patterns have a first combined area, and wherein the second patterns have a second combined area; and
wherein a ratio of the second combined area to the first combined area is less than about 30 percent.

16. The mask set of claim 15, wherein the first region comprises an entire chip, and wherein the ratio is between about 8 percent and about 20 percent.

17. The mask set of claim 15, wherein the first region has a width and a length each being greater than about 5 mm.

18. The mask set of claim 17, wherein the ratio is between about 8 percent and about 30 percent.

19. The mask set of claim 15, wherein the p-type regions further comprise at least a third pattern in addition to the second patterns, wherein the third pattern is not for forming SiGe.

20. The mask set of claim 15, wherein the p-type regions in the first region comprise p-type active regions and p-type inactive regions, and wherein the n-type regions in the first region comprise n-type active regions and n-type inactive regions.
